(19) United States
(12) Patent Application Publication
(10) Pub. No.: US 2007/0096754 A1
(43) Pub. Date: May 3, 2007

(54) Method and system for analyzing single event upset in semiconductor devices

(75) Inventors: Michael T. Johnson, Plymouth, MN (US); Keith W. Golke, Minneapolis, MN (US); Pamela J. Vogt, Maple Grove, MN (US); David K. Nelson, Medicine Lake, MN (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International Inc., Morristown, NJ (US)

(21) Appl. No.: 11/265,824

(22) Filed: Nov. 3, 2005

(51) Int. Cl. G01R 31/302

(52) U.S. Cl. 324/750

(57) ABSTRACT

A simulation model is used to predict a semiconductor device's response to a single event upset. The simulation model is connected to a model of the semiconductor device to be tested. The simulation model switches in an impedance path between a node to be tested in the semiconductor device model and an opposite voltage supply until a predefined amount of charge has been reached via sourcing (for a low to high voltage transition) or sinking (for a high to low voltage transition). When the predefined amount of charge has been reached, the impedance path is switched out. The switching of the impedance path approximates the charge movement that occurs from a heavy ion strike passing through a sensitive volume. By varying the predefined amount of charge, the semiconductor device's susceptibility to SEU can be predicted without having to resort to physical testing.

### GOVERNMENT RIGHTS

The United States Government has acquired certain rights in this invention pursuant to Contract No. F29601-98-C-0163 awarded by the Air Force Research Labs.

### FIELD

The present invention relates generally to circuit modeling, and more particularly, relates to analyzing single event upset in semiconductor devices.

### BACKGROUND

Single Event Effect (SEE) is a disturbance in an active electronic device caused by a single, energetic particle. As semiconductor devices become smaller and smaller, transistor threshold voltages also decrease. These lower thresholds reduce the ionizing field charge per node required to cause errors. As a result, the semiconductor devices become more and more susceptible to transient upsets.

One type of SEE is single event upset (SEU). SEU is a radiation-induced error in a semiconductor device caused when charged particles lose energy by ionizing the medium through which they pass, leaving behind a wake of electron-hole pairs, which forms a parasitic conduction path. The parasitic conduction path may cause a false transition on a node. The false transition, or glitch, can propagate through the semiconductor device and may ultimately result in the disturbance of a node containing state information, such as an output of a latch, register, or gate. One type of SEU is a single event transient (SET). SET occurs when a cosmic particle strikes a sensitive node within a combinational logic circuit. A voltage disturbance produced at that node may propagate through the logic.

Typically, SEU is caused by ionizing radiation components in the atmosphere, such as neutrons, protons, and heavy ions. The ionizing radiation components are abundant in space and at commercial flight altitudes. Additionally, SEU can be caused by alpha particles from the decay of trace concentrations of uranium and thorium present in some integrated circuit packaging. As another example, SEU may be caused as a result of detonating nuclear weapons. When a nuclear weapon is detonated, intense fluxes of gamma rays, x-rays, and other high energy particles are created.

Some semiconductor devices are designed to operate in conditions that expose the devices to energetic particles. However, external testing to determine which semiconductor devices can withstand SEU is costly and time consuming. Therefore, it would be beneficial to be able analyze and predict which semiconductor devices are suitable for operating in these conditions prior to performing external testing. As a result of being able to analyze and predict which semiconductor devices are suitable for operating in the presence of energetic particles, design and testing costs may be reduced.

### SUMMARY

A method and system for analyzing a response of a modeled device to a single event upset is described. An example method includes running a simulation that simulates applying a charge to a node of the modeled device. The charge is designed to mimic a charge deposition of an ion strike on the node. The method also includes determining whether the simulation causes an upset to the node and varying the applied charge to identify a range of charge values that can cause an upset to the node.

Running the simulation includes switching in a set of devices to create an impedance path between the node and a supply until a selected charge value is applied to the node. The supply is either VDD or VSS. The impedance path is switched out when the node reaches a predefined charge value. The switching of the impedance path approkimates charge movement that occurs during the ion strike. The simulation is limited to a range of charge values to limit voltage on the node to values between VDD and VSS.

The method may also include initializing the simulation. The initialization includes at least identifying the node, the charge to be applied, and an upper and lower charge limit for varying the applied charge.

The results of the simulation may be recorded. The results may include a critical charge level, Which is a charge value that caused an upset to the node. The method may also include comparing the critical charge level to a single event upset table. The comparison can be used to scale the results of the simulation. The results of the simulation may also be used to determine a threshold charge at which no upset of the node occurs.

A system for analyzing a response to a modeled device to a single event upset is also described. The system includes a processor, data storage, and machine language instructions stored in the data storage and executable by the processor. The processor may run a simulation that applies a charge to a node of a modeled device. The charge is designed to mimic a charge deposition of an ion strike on the node. The processor may determine whether the simulation causes an upset to the node and may vary the applied charge to identify a range of charge values that causes an upset to the node.

A simulation model for use in analyzing a response of a modeled device to a single event upset is also described. The simulation model may include an enable circuit that receives an input signal to initiate a simulation of the simulation model connected to a node of the modeled device. The simulation model also includes a charge circuit connected to the enable circuit and the node in the modeled device. The enable circuit causes an impedance path to be formed in the charge circuit upon activation by the input signal. The impedance path causes a charge to be applied to or removed from the node, thereby simulating a charge deposition of an ion strike on the node.

The simulation model may be a schematic-based representation of a circuit. Alternatively, the simulation model may be a netlist representation of a circuit. The modeled device may also be either a schematic representation or a netlist representation of the device to be simulated.

The input signal is a voltage applied to the enable circuit. The enable circuit removes the impedance path when a predetermined amount of charge is transferred. The charge circuit includes a monitoring node to monitor the amount charge transferred. The amount of charge transferred is calculated using a voltage level on the monitoring node.

The system and method for analyzing a response of a modeled device to a single event upset may be used to design devices able to withstand SEU. The operation of the device is simulated and its hardness to SEU is evaluated prior to and/or instead of evaluating the device under real-life conditions, which may be expensive and/or dangerous depending on the type of application in which the device is to be used. Additionally, hardening methods developed in the future can be analyzed using the system and method for analyzing a response of a modeled device to a single event upset. As a result of being able to analyze and predict which devices and hardening methods are suitable for operating in the presence of energetic particles, design and testing costs may be reduced.

These as well as other aspects and advantages will become apparent to those of ordinary skill in the art by reading the following detailed description, with reference where appropriate to the accompanying drawings. Further, it is understood that this summary is merely an example and is not intended to limit the scope of the invention as claimed.

### BRIEF DESCRIPTION OF THE DRAWINGS

Presently preferred embodiments are described below in conjunction with the appended drawing figures, wherein like reference numerals refer to like elements in the various figures, and wherein:

FIG. 1 depicts a block diagram of a simulation model used for analyzing a response of a semiconductor device to SEU, according to an example;

FIG. 2 depicts a circuit diagram of an enable circuit that can be used in the simulation model depicted in FIG. 1, according to an example;

FIG. 3 depicts a circuit diagram of a charge circuit that can be used in the simulation model depicted in FIG. 1, according to an example; and

FIG. 4 depicts a flowchart used to determine minimum charge necessary to cause upset in the semiconductor device, according to an example.

### DETAILED DESCRIPTION

A simulation model may be used to predict a semiconductor device's response to SEU. The simulation model may be connected to a model of the semiconductor device to be tested or simulated. A circuit simulation software package may be then be used to simulate the operation of the semiconductor device when an energetic particle is deposited on a node in the semiconductor device. SPICE is one of the most common circuit simulation programs; however, other circuit simulation programs may be used, including custom simulation programs. The results of the simulation may be used to determine the device's susceptibility to natural and/or manmade high-energy ions.

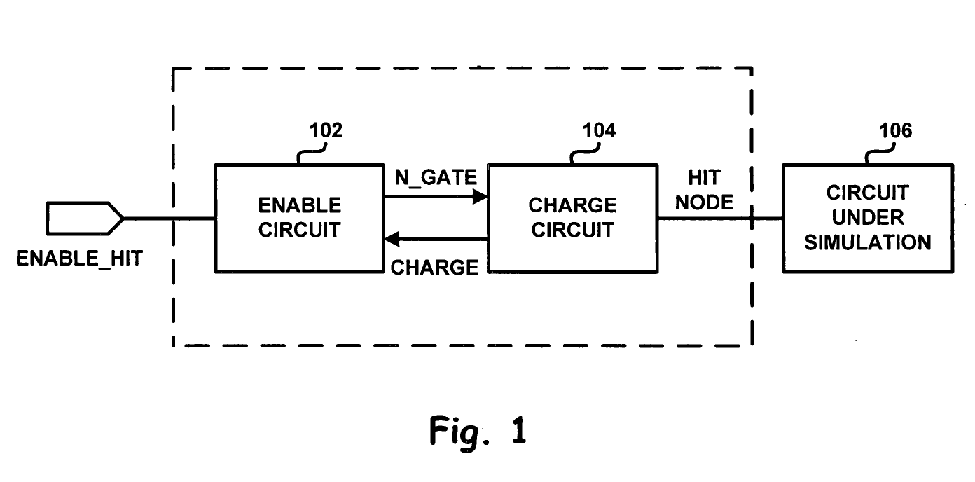

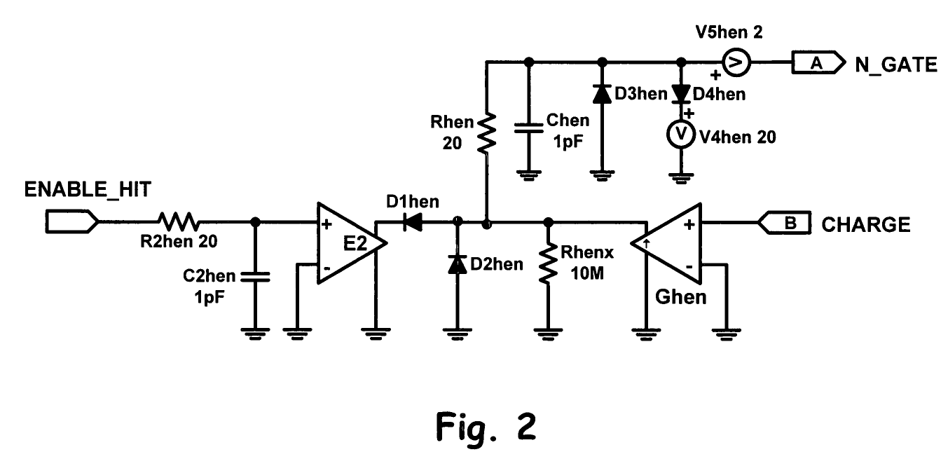

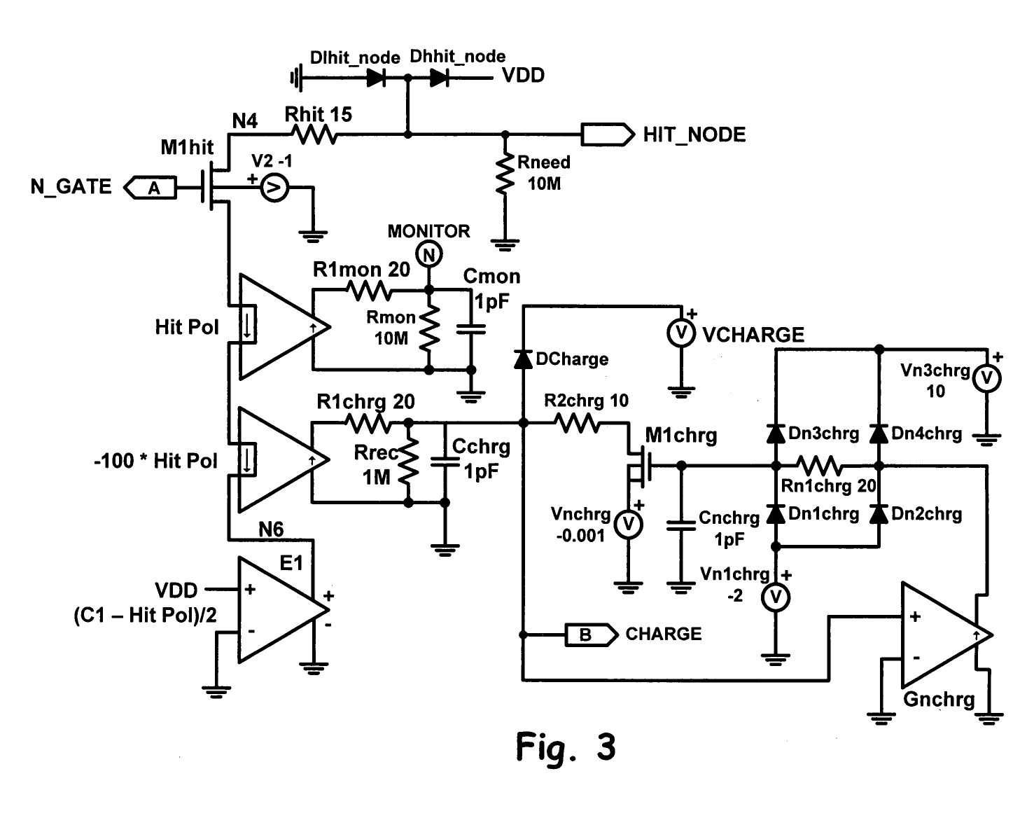

FIG. 1 depicts a block diagram of a simulation model 100 used for analyzing a response of a semiconductor device to SEU. The simulation model 100 is depicted in FIGS. 2-3 as a schematic; however, the simulation model 100 may also be represented as a netlist. An example netlist is provided in Appendix A. Other models that perform similarly to the simulation model 100 may also be used to analyze the response of a semiconductor device to SEU.

The simulation model 100 includes an enable circuit 102 connected to a charge circuit 104. The simulation model 100 may include additional circuitry. The simulation model 100 receives an enable input (Enable_Hit). The enable input is connected to the enable circuit 102 and is used to start the simulation. The charge circuit 104 is connected to a circuit under simulation 106.

The circuit under simulation 106 is a model of a circuit that includes the device whose response to SEU is to be analyzed by the simulation model 100. For example, the device may be a transistor. The behavior of the transistor may be monitored as a simulated SEU hit occurs between a source and a drain, and beneath a gate of the transistor. The charge circuit 104 is connected to a node to be tested (i.e., the node of concern) in the circuit under simulation 106. The node of concern is also referred to as a Hit₁₃ Node. The enable input starts the application of a charge to the node of concern in the circuit under simulation 106 through the Hit_Node connection.

The simulation model 100 is designed to mimic a charge deposition of a high-energy ion strike on a sensitive node in a semiconductor device. In addition, the simulation model 100 is designed to limit charge flow into or out of the sensitive node so that the node is not pulled above a supply voltage VDD+V_{DIODE} or does not drop below VSS−V_{DIODE}. The simulation model 100 switches in an impedance path between the node of concern and an opposite voltage supply until a predefined amount of charge has been reached via sourcing (for a low to high voltage transition) or sinking (for a high to low voltage transition). When the predefined amount of charge has been reached, the impedance path is switched out. The switching of the impedance path approximates the charge movement that occurs from a heavy ion strike passing through a sensitive volume, such as a reverse biased junction region.

While the functions of the simulation model 100 can be implemented in many ways, example circuit models for the enable circuit 102 and the charge circuit 104 are depicted in FIGS. 2-3. Device names in FIGS. 2-3 correspond to the netlist provided as an example in Appendix A.

FIG. 2 depicts a circuit diagram of an enable circuit 200 that can be used in the simulation model 100 depicted in FIG. 1. The enable circuit 200 is connected to the ENABLE_HIT input of the simulation model 100, and the N-Gate port (A) and CHARGE port (B) of the charge circuit 104. The purpose of the enable circuit 200 is to control the M1hit transistor of the charge circuit 104.

The CHARGE port (B) is initialized to a voltage equivalent to Qhit*100/1pf (i.e., if a simulation with a 1pC of charge is desired, then CHARGE is initially set to 100V). To activate the simulation, the ENABLE_HIT port is stimulated with a 20V positive voltage. This turns on the M1hit transistor in the charge circuit 300 (shown in FIG. 3) via the N_GATE port (A). Activating the M1hit transistor, switches in the impedance path (Rhit) and starts the Qhit simulation. Once sufficient charge has been added to (or removed from) the circuit under simulation 106, the CHARGE port (B) goes negative causing the enable circuit 200 to turn off the M1hit transistor, ceasing any further charge transfer from the circuit under simulation 106.

FIG. 3 depicts a circuit diagram of a charge circuit 300 that can be used in the simulation model 100 depicted in FIG. 1. The charge circuit 300 provides a means of controlling the amount of charge transferred from the circuit under simulation 106, monitoring the effective charge that has been transferred (see monitor node N), and signaling the enable circuit 200 to switch out the impedance path (Rhit) to the circuit under simulation 106.

As previously described, the CHARGE port (B) is initialized to a desired level. “Hit Pol” is a user defined value that is set to +1 for low-to-high hits (i.e., charge injected into the circuit under simulation 106) or to −1 for high-to-low hits (i.e., charge removed from the circuit under simulation 106). Upon activation of the enable circuit 200, the M1hit transistor turns on, connecting the circuit under simulation 106 to either VSS or VDD through a low impedance (Rhit) depending on the state of Hit Pol. This transfers charge into or out of the circuit under simulation 106, depending upon the state of Hit Pol.

During the charge transfer phase of the simulation, the monitor node N is charged to a voltage level substantially equal to Qhit/1pf, mirroring the charge transferred through the Hit_Node. The voltage of the CHARGE port (B) decreases at a rate of 100*Qhit/1pf. When the CHARGE port (B) drops to a negative voltage, signaling that the target charge has been moved, the M1 chrg transistor is activated, which clamps the CHARGE port (B) to a negative potential. The CHARGE signal disables the enable circuit 200, which turns off the M1hit transistor and disconnects the Hit_Node from the impedance path to the supply. The charge that was transferred from the circuit under simulation 106 may be determined by a calculation based on the final simulation voltage on the monitor node N.

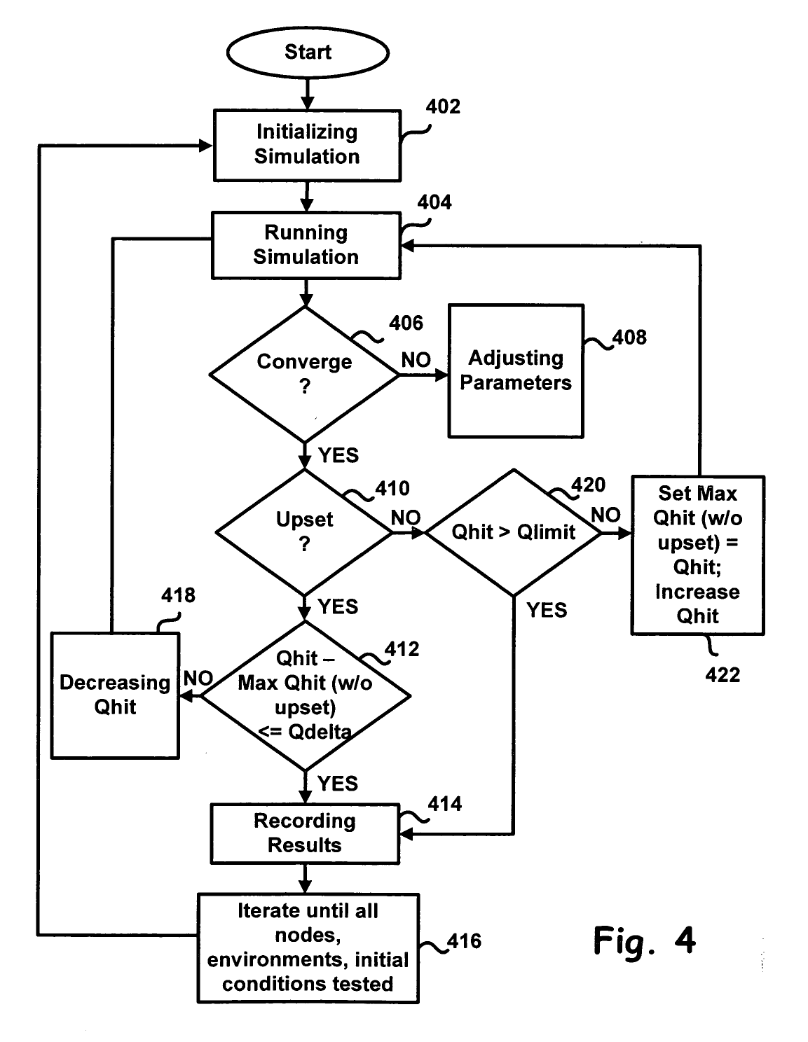

FIG. 4 depicts a flowchart of a method 400 for determining what minimum charge applied to a node of concern can cause an upset to that node. The charge applied to the node of concern during simulation is called Qhit. Qhit is varied during the simulation to find upper and/or lower boundaries of the range of charges that can cause an upset to the node of concern. The simulation results may be used to determine a threshold charge at which no disturbance to the node of concern occurs.

At block 402, the simulation is initialized. The initialization includes identifying the node of concern in the semiconductor device to be tested. The semiconductor device to be simulated is modeled. The model of the semiconductor device may be in the form of a schematic Or a netlist. The semiconductor device model is connected to the simulation model at the selected node of concern. The simulation model may also be in the form of a schematic or a netlist, such as the schematics depicted in FIGS. 2-3 or the netlist provided in Appendix A.

The initialization also includes identifying the environment in which the semiconductor device is to be operated and the initial conditions of the semiconductor device. Other initial conditions may be identified. These initial conditions may be identified in the form of one or more lists. The list(s) of initial conditions may be incorporated into the device and/or simulation models as appropriate.

The initialization also includes identifying the initial charge (Qhit) to be applied to the node of concern. Additionally, a maximum charge limit (Qlimit) and a minimum delta critical charge (Qdelta) may be selected. Qlimit is the maximum charge allowed in the simulation and may be selected to limit the charge flow into or out of the node so that the node is not pulled above the supply voltage VDD or drops below VSS. Qdelta is the minimum delta of the critical charge. Qdelta may be selected based on the desired resolution of the simulation and is usually set to 5-10% of the target value. The initialization also includes setting a variable “Max Qhit(w/o upset)” to zero.

At block 404, the simulation is run. The simulation switches in an impedance path between the node of concern and an opposite voltage supply until Qhit has been reached via sourcing (for a low to high voltage transition) or sinking (for a high to low voltage transition). When Qhit has been reached, the impedance path is switched out.

At block 406, convergence of the simulation is checked to determine if the simulation properly finishes. Occasionally during simulation, the simulation software is unable to finish its analysis. This may be more of problem when running a simulation that requires a nonlinear analysis. If the simulation fails to converge, at block 408 parameters of the simulation model and/or the device model are adjusted. For example, changing the Qhit by 5% may be enough to cause the simulation to converge;

At block 410, determining whether the simulation caused an upset is evaluated. If an upset did occur, at block 412, the difference between Qhit and Max Qhit(w/o upset) (i.e., Qhit−Max Qhit(w/o upset)) is compared with Qdelta. If the difference is less than or equal to Qdelta, then at block 414 the results of the simulation are recorded. The max Qhit(w/o upset) is recorded as a critical charge level. The selected node of concern, environment, and initial conditions are also recorded.

At block 416, simulation conditions may be varied and these conditions may be initialized at block 402. The simulation conditions may be varied until all nodes of concern in the semiconductor device model, environment, and initial condition combinations have been evaluated. Not all nodes in a circuit design need to be evaluated as some nodes are not impacted by SEU.

Returning back to block 412: if the difference between Qhit and max Qhit(w/o upset) is greater than Qdelta, then at block 418 Qhit is decreased and the simulation is run at block 404 with this new value of Qhit.

Returning back to block 410: if an upset did not occur, at block 420 Qhit is compared with Qlimit. If Qhit is greater than Qlimit, then at block 414 the results of the simulation are recorded. The max Qhit(w/o upset) is recorded as a critical charge level. The selected node of concern, environment, and initial conditions are also recorded. If Qhit is not greater than Qlimit, at block 422 the variable Max Qhit(w/o upset) is set equal to Qhit and then Qhit is increased. The simulation is run again at block 404 with these changes to Max Qhit(w/o upset) and Qhit.

Additional steps may be performed after recording the results of the simulation at block 414. For example, the critical charge level and the dimensions of the semiconductor device being tested may be compared to known SEU upset tables. Based on the information obtained from this comparison, the results of the simulation may be scaled based on a likelihood of an upset occurring. This scaled result may then be recorded.

The simulation model 100 and the method 400 for predicting response to SEU may be used to design circuitry able to withstand SEU. This circuitry is simulated and its hardness to SEU is evaluated prior to and/or instead of evaluating the circuitry under real-life conditions, which may be expensive and/or dangerous depending on the type of application in which the circuitry is to be used. Additionally, hardening methods developed in the future can be analyzed using the simulation model 100 and the method 400. As a result of being able to analyze and predict which semiconductor devices and hardening methods are suitable for operating in the presence of energetic particles, design and testing costs may be reduced.

It should be understood that the illustrated embodiments are examples only and should not be taken as limiting the scope of the present invention. The claims should not be read as limited to the described order or elements unless stated to that effect. Therefore, all embodiments that come within the scope and spirit of the following claims and equivalents thereto are claimed as the invention.

APPENDIX A
Netlist of Simulation Model 100

.subckt seu_hit hit_node_resit seu_hit_mon VDD
* IDEAL DIODE MODEL
*
* EGO, XTI, AND ALPHAB ARE SET TO ZERO TO CANCEL TEMPERATURE
EFFECTS ON IS
* IT APPEARS THAT SPICE USES VT=25.7MV AT 300 DEGREES K.
* THE DIODE CURRENT IS THEN ID = IS * (EXP(VD/(N*VT)) − 1)
*
.MODEL SEU5 D IS=10N N=0.5 EGO=0 XTI=0 ALPHAB=0
******************
* TRANSISTOR ‘switch’
*
.MODEL NCH_VT1 NMOS LEVEL=3 VTO=1.00 TOX=0.265U NSUB=1.5E16
UO=2E5
+CJ=0 MJ=0 CJSW=0 MJSW=0 CGSO=0 CGDO=0 CGBO=0 JS=1E−9
******************
*
.options tnom=27 newton
V_SEU_Hit_V5hen SEU_Hit_N3 SEU_Hit_Ngate 2
V_SEU_Hit_Vnchrg SEU_Hit_N_476 0 −.001
V_SEU_Hit_Vn1chrg_s SEU_Hit_N_13 0 −2
V_SEU_Hit_Vn3chrg SEU_Hit_N_12 0 10
V_SEU_Hit_V4hen SEU_Hit_N_9 0 20
V_SEU_Hit_V2 SEU_Hit_N8 0 −1.0
R_SEU_Hit_Rhit SEU_Hit_N4 hit_node_resit 15
R_SEU_Hit_R2hen SEU_Hit_N1 hit_it 20
R_SEU_Hit_R2chrg SEU_Hit_Charge SEU_Hit_N9 10
R_SEU_Hit_Rret VSS 0 10MEG
R_SEU_Hit_R1chrg SEU_Hit_N_1498 SEU_Hit_Charge 20
R_SEU_Hit_Rn1chrg SEU_Hit_N10 SEU_Hit_N11 20
R_SEU_Hit_Rhen SEU_Hit_N2 SEU_Hit_N3 20
R_SEU_Hit_Rneed hit_node_resit 0 10MEG
R_SEU_Hit_Rmon seu_hit_mon 0 10MEG
R_SEU_Hit_R1mon SEU_Hit_N_1705 seu_hit_mon 20
R_SEU_Hit_Rhenx SEU_Hit_N2 0 10MEG
R_SEU_Hit_Rrec SEU_Hit_Charge 0 1000000
C_SEU_Hit_Cret VSS 0 1 fF
C_SEU_Hit_Cmon seu_hit_mon 0 1pF
C_SEU_Hit_C2hen SEU_Hit_N1 0 1pF
C_SEU_Hit_Chen SEU_Hit_N3 0 1pF
C_SEU_Hit_Cnchrg SEU_Hit_N10 0 1pF
C_SEU_Hit_Cchrg SEU_Hit_Charge 0 1pF
D_SEU_Hit_Dn1chrg SEU_Hit_N_13 SEU_Hit_N10 SEU5
D_SEU_Hit_D4hen SEU_Hit_N3 SEU_Hit_N_9 SEU5
D_SEU_Hit_DCharge SEU_Hit_Charge SEU_Hit_N_882 SEU5
D_SEU_Hit_D2hen 0 SEU_Hit_N2 SEU5
D_SEU_Hit_D3hen 0 SEU_Hit_N3 SEU5
D_SEU_Hit_Dn2chrg SEU_Hit_N_13 SEU_Hit_N11 SEU5
D_SEU_Hit_Dhhit_node hit_node_resit VDD SEU5
D_SEU_Hit_Dlhit_node 0 hit_node_resit SEU5
D_SEU_Hit_Dn3chrg SEU_Hit_N10 SEU_Hit_N_12 SEU5
D_SEU_Hit_D1hen SEU_Hit_N2 SEU_Hit_N_1294 SEU5
D_SEU_Hit_Dn4chrg SEU_Hit_N11 SEU_Hit N_12 SEU5
VF_SEU_Hit_F11 SEU_Hit_N5 SEU_Hit_N6 DC 0
VF_SEU_Hit_Fmon1 SEU_Hit_N_1708 SEU_Hit_N5 DC 0
G_SEU_Hit_Ghen 0 SEU_Hit_N2 POLY(1) SEU_Hit_Charge 0 0 10000
G_SEU_Hit_Gnchrg 0 SEU_Hit_N11 POLY(1) SEU_Hit_Charge 0 0 −10000
E_SEU_Hit_E2 SEU_Hit_N_1294 0 POLY(1) SEU_Hit_N1 0 0 1
M_SEU_Hit_M1hit SEU_Hit_N4 SEU_Hit_Ngate SEU_Hit_N_1708 SEU_Hit_N8
NCH_vt1 W=1U L=0.3U
M_SEU_Hit_M1chrg SEU_Hit_N9 SEU_Hit_N10 SEU_Hit_N_476 SEU_Hit_N_476
NCH_vt1 W=1U L=0.3U
.op
*
*-----------------------------------------------------------
* Triggering voltage pulse command line to start Qdep.
V_HIT_IT HIT_IT 0 PULSE −1 20 1E−10 5E−11 5E−11 1E−06 2E−06
*
E_SEU_Hit_E1 SEU_Hit_N6 0 POLY(1) VDD 0 0 EVAL
F_SEU_Hit_Fmon 0 SEU_Hit_N_1705 POLY(1) VF_SEU_Hit_Fmon1 0 FVAL1
F_SEU_Hit_F1 0 SEU_Hit_N_1498 POLY(1) VF_SEU_Hit_F11 0 FVAL2
*
* For lh hit the above becomes the following three lines:
*E_SEU_Hit_E1 SEU_Hit_N6 0 POLY(1) VDD 0 0 1
*F_SEU_Hit_Fmon 0 SEU_Hit_N_1705 POLY(1) VF_SEU_Hit_Fmon1 0 −1
*F_SEU_Hit_F1 0 SEU_Hit_N_1498 POLY(1) VF_SEU_Hit_F11 0 100
*
* For hl hit the above becomes the following three lines:
*E_SEU_Hit_E1 SEU_Hit_N6 0 POLY(1) VDD 0 0 0
*F_SEU_Hit_Fmon 0 SEU_Hit_N_1705 POLY(1) VF_SEU_Hit_Fmon1 0 1
*F_SEU_Hit_F1 0 SEU_Hit_N_1498 POLY(1) VF_SEU_Hit F11 0 −100
*
* The following 2 lines are used to set the deposited charge:
V_SEU_Hit_VCharge SEU_Hit_N_882 0 DC VCharge
.IC V(SEU_HIT_CHARGE)=VCharge
* The deposited charge is defined by setting VCharge to a number.
* Set VCharge to 100 times the desired Q deposited.
* For example:
* If want to deposit 1pC then:
* V_SEU_Hit_VCharge SEU_Hit_N_882 0 DC 100
* .IC V(SEU_HIT_CHARGE)=100
*------------------------------------------------------------
*
.IC V(seu_hit_mon)=0
*
.ends seu_hit

We claim:

1. A method for analyzing a response of a modeled device to a single event upset, comprising in combination:
running a simulation that simulates applying a charge to a node of the modeled device, wherein the charge is designed to mimic a charge deposition of an ion strike on the node;
determining whether the simulation causes an upset to the node; and
varying the applied charge to identify a range of charge values that causes an upset to the node.

2. The method of claim 1, wherein running the simulation includes switching an impedance path between the node and a supply until a selected charge value is applied to the node.

3. The method of claim 2, wherein the supply is one of VDD and VSS.

4. The method of claim 2, wherein the impedance path is switched out when the node reaches a predetermined charge value.

5. The method of claim 4, wherein the switching of the impedance path approximates charge movement that occurs during the ion strike.

6. The method of claim 1, wherein the simulation is limited to a range of charge values to limit voltage on the node to values between VDD and VSS.

7. The method of claim 1, further comprising initializing the simulation.

8. The method of claim 7, wherein the initialization includes identifying the node, the charge to be applied, and an upper and lower charge limit for varying the applied charge.

9. The method of claim 1, further comprising recording results of the simulation, wherein the results include a critical charge, and wherein the critical charge is a charge value that caused an upset to the node.

10. The method of claim 9, further comprising comparing the critical charge level to a single event upset table, wherein the comparison is used to scale the results of the simulation.

11. The method of claim 1, further comprising using results of the simulation to determine a threshold charge at which no upset of the node occurs.

12. A system for analyzing a response to a modeled device to a single event upset, comprising in combination:
a processor;
data storage; and
machine language instructions stored in the data storage executable by the processor to:
run a simulation that applies a charge to a node of a modeled device, wherein the charge is designed to mimic a charge deposition of an ion strike on the node;
determine whether the simulation causes an upset to the node; and
vary the applied charge to identify a range of charge values that causes an upset to the node.

13. A simulation model for use in analyzing a response of a modeled device to a single event upset, comprising in combination:
an enable circuit that receives an input signal to initiate a simulation of the simulation model connected to a node of the modeled device; and
a charge circuit connected to the enable circuit and the node in the modeled device, wherein the enable circuit causes an impedance path to be formed in the charge circuit upon activation by the input signal, wherein the impedance path causes a charge to be applied to or removed from the node, thereby simulating a charge deposition of an ion strike on the node.

14. The simulation model of claim 13, wherein the simulation model is a schematic-based representation of a circuit.

15. The simulation model of claim 13, wherein the simulation model is a netlist representation of a circuit.

16. The simulation model of claim 13, wherein the input signal is a voltage applied to the enable circuit.

17. The simulation model of claim 13, wherein the enable circuit removes the impedance path when a predetermined amount of charge is transferred.

18. The simulation model of claim 17, wherein the charge circuit includes a monitoring node to monitor the amount charge transferred.

19. The simulation model of claim 18, wherein the amount of charge transferred is calculated using a voltage level on the monitoring node.
